(19) United States
(12) Patent Application Publication
(10) Pub. No.: US 2024/0077522 A1
(43) Pub. Date: Mar. 7, 2024

(54) VOLTAGE MONITORING DEVICES AND METHODS

(71) Applicants: STMicroelectronics (Alps) SAS, Grenoble (FR); STMicroelectronics (Grenoble 2) SAS, Grenoble (FR)

(72) Inventors: Christophe Lorin, Montbonnot (FR); Nathalie Dubois, Sassenage (FR)

(21) Appl. No.: 18/355,977

(22) Filed: Jul. 20, 2023

(30) Foreign Application Priority Data
Sep. 2, 2022 (FR) 2208832

(51) Int. Cl. G01R 19/165; G01R 15/04

(52) U.S. Cl. CPC G01R 19/16576; G01R 15/04

(57) ABSTRACT

A voltage matching circuit receives a first voltage received by a connector, and outputs a second voltage. The second voltage is equal to the first voltage, if the first voltage is less than a threshold voltage. The second voltage is equal to the first voltage divided by a first factor, if the first voltage is greater than or equal to the threshold voltage.

### CROSS-REFERENCE TO RELATED APPLICATIONS

This application claims priority to French Application No. 2208832, filed on Sep. 2, 2023, which application is hereby incorporated herein by reference.

### TECHNICAL FIELD

The present disclosure generally relates to electronic systems and devices, and more particularly to the electronic systems and devices adapted to the USB T e-C technology and to the USB PD protocol. The present disclosure relates more precisely to a part of a control circuit of a connector adapted to the USB PD-C technology.

### BACKGROUND

The USB (“Universal Serial Bus”) technology is a standard of computer bus used to couple any type of electronic devices with each other, and allowing them to exchange data, and/or power. The USB technology changes over time, and one of its last versions, the USB Type-C technology implementing the energy transfer protocol USB PD is able to exchange higher powers, that is, for example, powers higher than 100 W on the basis of a voltage higher than 20 V.

It would be desirable to be able to improve at least in part some aspects of the electronic devices adapted to implement the USB T e-C technology.

### SUMMARY

The present disclosure generally relates to electronic systems and devices, and more particularly to the electronic systems and devices adapted to the USB T e-C technology and to the USB PD protocol. The present disclosure relates more particularly to a part of a control circuit of a connector adapted to the USB PD-C technology.

There is a need for devices adapted to implement the USB T e-C technology and the USB PD protocol adapted to receive a power higher than 100 W on the basis of a voltage higher than 20 V.

There is a need for devices adapted to implement the USB T e-C technology and the USB PD protocol adapted to receive a power in the order of 240 W on the basis of a voltage in the order of 48 V.

There is a need for a circuit allowing devices adapted to implement the USB T e-C technology and the USB PD protocol already existing to receive a power in the order of 240 W on the basis of a voltage in the order of 48 V.

One or more embodiments address all or some of the drawbacks of known devices adapted to implement the USB T e-C technology.

In one or more embodiments, a voltage matching circuit is provided that is configured to receive a first voltage received by a connector, and output a second voltage, the second voltage equal to:
the first voltage, in response to the first voltage being less than a threshold voltage; or
the first voltage divided by a first factor, in response to the first voltage being greater than or equal to the threshold voltage.

According to an embodiment, the voltage matching circuit comprises a comparator circuit configured to compare the first voltage with the threshold voltage.

According to an embodiment, the voltage matching circuit comprises a division circuit configured to divide the first voltage by the first factor.

According to an embodiment, the second circuit comprises a voltage divider bridge.

According to an embodiment, the first factor is in the order of 3.

According to an embodiment, the voltage matching circuit comprises a selection circuit configured to couple output the second voltage by selectively coupling an output node with either with a first node at the first voltage, or with a second node at a voltage equal to the first voltage divided by the first factor.

According to an embodiment, the selection circuit is configured to be controlled by an output voltage of the comparator circuit.

According to an embodiment, the selection circuit is further configured to be controlled by a control voltage.

According to an embodiment, the control voltage is a voltage indicating if the connector is supposed to receive the first voltage at a voltage that is greater than the threshold voltage or not.

According to an embodiment, the connector is adapted to a USB T e-C connector configured to implement USB PD protocol.

Another embodiment provides an electronic device comprising the matching voltage circuit previously described.

According to an embodiment, the circuit further comprises a monitoring circuit configured to receive the second voltage output by the voltage matching circuit.

According to an embodiment, the monitoring circuit is configured to monitor a voltage less than 20 V.

According to an embodiment, the electronic device further comprises a connector.

Another embodiment provides a method that includes: monitoring a first voltage received by a connector; and outputting a second voltage, the second voltage being equal to: the first voltage, in response to the first voltage being less than a threshold voltage; or the first voltage divided by a first factor, in response to the first voltage being greater than or equal to the threshold voltage.

In one or more embodiments, the method includes comparing, by a comparator circuit, the first voltage with the threshold voltage.

In one or more embodiments, the method includes dividing, by a division circuit, the first voltage by the first factor.

In one or more embodiments, the method includes outputting, by a selection circuit, the second voltage by selectively coupling an output node with either with a first node at the first voltage, or with a second node at a voltage equal to the first voltage divided by the first factor.

In one or more embodiments, the method includes controlling the selection circuit by an output voltage of a comparator circuit.

In one or more embodiments, the method includes controlling the selection circuit by a control voltage, the control voltage indicating whether the connector is supposed to receive the first voltage at a voltage that is greater than or less than the threshold voltage.

### BRIEF DESCRIPTION OF THE DRAWINGS

For a more complete understanding of one or more embodiments of the present disclosure, and the advantages thereof, reference is now made to the following descriptions taken in conjunction with the accompanying drawings, in which:

FIG. 1 schematically illustrates in block form an example USB T e-C connection between two electronic devices, in accordance with one or more embodiments;

FIG. 2 illustrates a graph representing, for a given power, the different voltage/current couples transferable using the USB T e-C technology and the USB PD protocol, in accordance with one or more embodiments;

FIG. 3 illustrates a schematic view of a connector adapted to the USB T e-C technology and to the USB PD protocol, in accordance with one or more embodiments;

FIG. 4 schematically illustrates in block form a voltage monitoring circuit, in accordance with one or more embodiments;

FIG. 5 illustrates details of a voltage monitoring circuit, in accordance with one or more embodiments; and

FIG. 6 illustrates graphs representing operation of the voltage monitoring circuit of FIG. 4, in accordance with one or more embodiments.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For the sake of clarity, only the operations and elements that are useful for an understanding of the embodiments described herein have been illustrated and described in detail. For example, the different data-exchange protocols used with the connectors according to the embodiments described hereinafter are not detailed, such protocols being, for the majority, compatible with the described embodiments.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “in the order of”, “approximately”, and “substantially” signify within 10%, and in some embodiments within 5%.

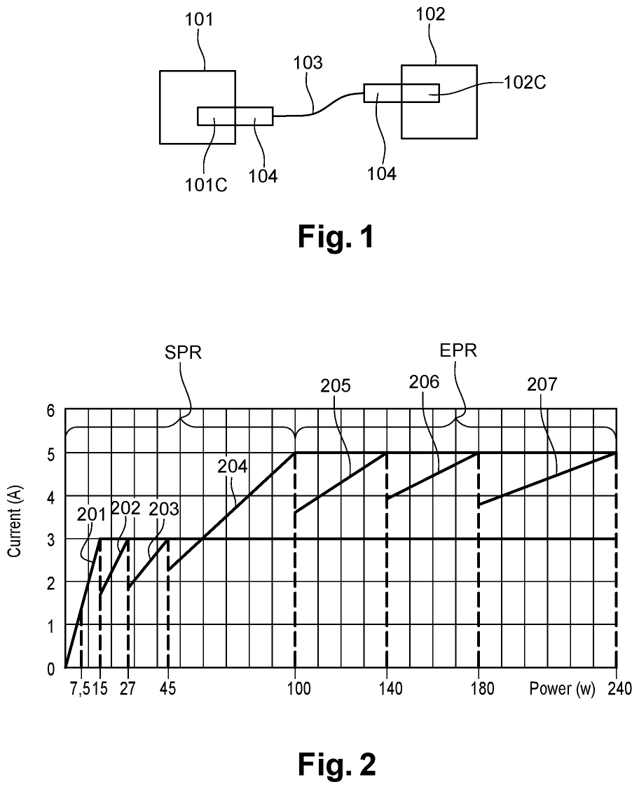

FIG. 1 schematically illustrates in block form two electronic devices 101 and 102 coupled with each other via a connection cable 103.

The devices 101 and 102 are according to the example described in relation with FIG. 1, each respectively provided with a connector 101C, 102C. The connection cable 103 is provided, at each of its ends, with connectors 104 adapted to cooperate with the connectors 101C and 102C of the devices 101 and 102. According to an example, the connectors 104 are male-type connectors, and the connectors 101C and 102C are female-type connectors. Alternatively, the connectors 104 are female-type connectors, and the connectors 101C and 102C are male-type connectors.

According to another alternative, the devices 101 and 102 may be coupled without connection cable. In such case, the connector 101C, or vice-versa the connector 102C, is a male-type connector, and the connector 102C, or vice-versa the connector 101C, is a female-type connector.

Connectors 101C, 102C, and 104 generally are all constituted of mechanical means of connection, which may be any suitable mechanical connector or the like, and of one or more circuits adapted to implement electronic connection between the devices 101, 102.

According to an embodiment, the cable 103 and the connectors 101C, 102C, and 104 are adapted to implement the USB (Universal Serial Bus) technology allowing data, but also energy, to be exchanged. The USB technology is defined by a standard relative to serial computer bus. Several USB technology types exist, the cable 103 and connectors 101C, 102C, and 104 are more particularly adapted to implement an USB T e-C technology. The specificity of the USB T e-C technology is it allows powers higher than wo W, and ranging up to 204 W, to be exchanged between two electronic devices. In addition, the USB T e-C technology may allow the USB PD protocol, also called USB Power Delivery protocol, to be implemented. This protocol is more detailed in relation with FIG. 2.

FIG. 2 illustrates a graph representing the operation of the energy-exchange USB PD protocol, and more particularly representing the different voltage/current couples, defined by a standard, for a given power, transferable using the USB T e-C technology and the USB PD protocol.

The USB PD protocol allows managing the energy exchange between two devices coupled by a USB T e-C technology, and more particularly allows the level of the exchanged electric power to be managed. More particularly, the electronic devices using this protocol are adapted to deliver, at their connector, several different current values and several different voltage values. These different current and voltage values are for example set at manufacturing according to the components of the device, and/or, for example, of the operation modes of the device. The different current values deliverable by a device implementing this protocol may for example be selected among the group consisting of: 1.5 A, 2 A, 3 A, and 5 A. The different voltage values deliverable by a device implementing this protocol may for example be selected among the group consisting of: 5 V, 9 V, 12 V, 15 V, 20 V, 28 V, 36 V, and 48 V. A value of the power supplied by a device is set by a couple comprising a current value and a voltage value. Such a couple is hereinafter called supply pattern.

The graph of FIG. 2 represents example supply patterns feasible with the USB PD protocol. The reading of a power value on x-axis allows determining the voltage/current couple set by the standard allowing obtaining this power. The graph comprises several curves each illustrating, for a given voltage value, the evolution of the electrical power transferred as a function of the current deliverable at this voltage value. More particularly, the graph represents seven curves in which: a curve 201 illustrating, for a voltage in the order of 5 V, a supplied electrical power comprised between 0 W and 15 W, consequently with a current varying between 0 and 3 A; a curve 202 illustrating, for a voltage in the order of 9 V, a supplied electrical power comprised between 15 W and 27 W, consequently with a current varying between 1.6 and 3 A;

a curve 203 illustrating, for a voltage in the order of 15 V, a supplied electrical power comprised between 27 W and 45 W, consequently with a current varying between 1.8 and 3 A; a curve 204 illustrating, for a voltage in the order of 20 V, a supplied electrical power comprised between 45 W and 100 W, consequently with a current varying between 2.25 and 5 A; a curve 205 illustrating, for a voltage in the order of 28 V, a supplied electrical power comprised between 100 W and 140 W, consequently with a current varying between 3.6 and 5 A; a curve 206 illustrating, for a voltage in the order of 36 V, a supplied electrical power comprised between 140 W and 180 W, consequently with a current varying between 3.8 and 5 A; and a curve 207 illustrating, for a voltage in the order of 48 V, a supplied electrical power comprised between 180 W and 240 W, consequently with a current varying between 3.75 and 5 A.

When an electrical device is able to output one of the supply patterns of curves 201-207 delivering an electrical power P1, it is also able to output all the supply patterns corresponding to electrical powers less than this electrical power P1. According to a practical example, if an electronic device is able to output the supply pattern providing a power of 45 W of curve 203, that is the supply pattern providing the current 15 V/3 A, it is also able to output the supply patterns providing the powers of 7.5 W of curve 201, 15 W of curve 202, and 27 W of curve 203.

The supply patterns represented with curves 201-204, that is the voltage/current couples and the powers associated with curves 201-204, constitute part of a first supply range SPR, or standard range SPR, corresponding to the standard supply patterns (Standard Power Range) of devices adapted to implement the USB PD protocol. These supply patterns are part of those considered in a first and older version of the USB PD protocol. Other supply patterns characterised by a transmitted power less than 100 W, or a voltage less than 20 V, may be part of the first supply range SPR.

The supply patterns represented in curves 205-207, that is the voltage/current couples and the associated powers of curves 205-207, are part of a second supply range EPR, or extended range EPR, corresponding to the extended power patterns (Extended Power Range) of the devices adapted to implement the USB PD protocol. These supply patterns are part of those considered in a second version of the USB PD protocol, corresponding to an extension of the first version. Other supply patterns characterised by a transmitted power higher than wo W, and ranging up to 240 W, or a voltage higher than 20 V, may be part of the extended supply range EPR.

Practically, when two devices K1 and K2 adapted to the USB T e-C technology and to USB PD protocol are coupled together, a supply, or where appropriate a recharge, of the device K1 by the device K2 occurs as follows. The devices K1 and K2 begin with indicating the supply patterns they are able to provide and receive. Follows a negotiation between devices K1 and K2 to determine which supply pattern is adapted to the supply of device K1. Once the supply pattern selected, the device K2 sends the current/voltage couple characterising said supply pattern, and the supply, or the charge where appropriate, of the device K1 is performed.

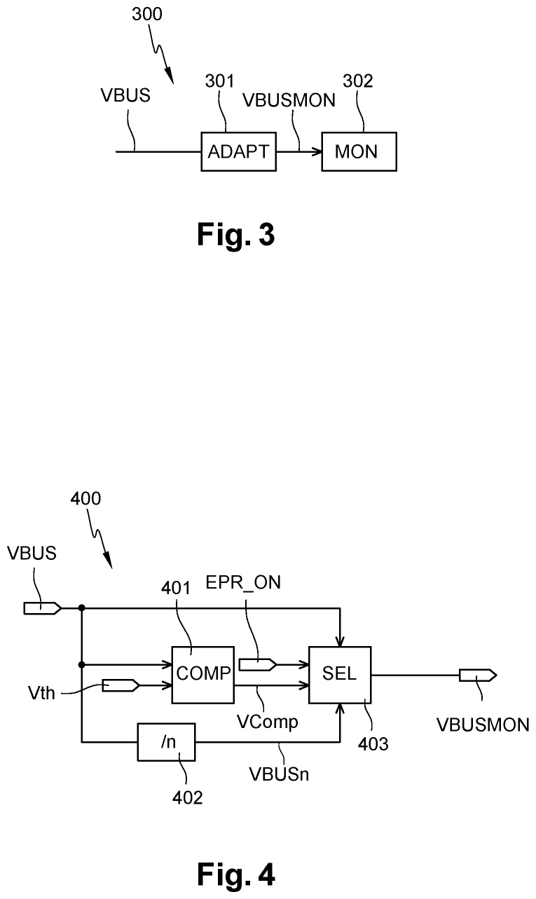

FIG. 3 schematically illustrates in a block form an embodiment of circuitry 300 associated with a connector adapted to the USB T e-C technology and to the USB PD protocol, of the type of connectors 101C or 102C described in relation with FIG. 1. In some embodiments, the circuitry 30o may be located within one or both of the connectors 101C, 102C.

The circuitry 30o receives, as an input, a voltage VBUS for example from a cable of the type of the cable 103 described in relation with FIG. 1. According to an example, the voltage VBUS may also correspond to a voltage outputted by the electronic device comprising the circuitry 30o to a cable of the type of cable 103.

Circuitry 30o comprises, on a first monitoring branch, a voltage matching circuit 301 (ADAPT) and a monitoring circuit 302 (MON). The voltage matching circuit receives, as an input, the voltage VBUS and delivers, as an output, a voltage VBUSMON to the monitoring circuit 302. Detailed examples of the circuit 301 are described in relation with FIGS. 4-6. The monitoring circuit 302 is adapted to monitor the voltage VBUSMON, being a voltage representative of the voltage VBUS, in order to implement the USB PD protocol.

FIG. 4 schematically illustrates in block form a voltage matching circuit 400, which may be the circuit 301 described in relation with FIG. 3, in some embodiments.

Voltage matching circuit 40o receives, as an input, the voltage VBUS, and delivers, as an output, the voltage VBUSMON. The voltage VBUS is a voltage delivered by an energy transfer cable adapted to the USB T e-C technology and to the USB PD protocol. According to an example, the voltage VBUS may also correspond to a voltage delivered by the electronic device comprising the circuitry 30o to a cable of the type of the cable 103. The voltage VBUSMON is a voltage representative of the voltage VBUS.

Circuit 400 further receives a threshold voltage Vth, and a control voltage EPR_ON, or control signal EPR_ON. As an example, the threshold voltage Vth is comprised between 10 and 20 V, for example in the order of 15 V. The voltage EPR_ON indicates if the supply pattern having been negotiated is a part of the standard range SPR or of the extended range EPR. In other words, the voltage EPR_ON indicates if the connector and the circuitry comprising the circuit 400 is supposed to receive a voltage VBUS higher than the threshold voltage Vth. According to an example, when the voltage EPR_ON is at a high level, the supply pattern is a part of the extended range EPR, and when the voltage EPR_ON is at a low level, the supply pattern is a part of the standard range SPR, or vice-versa. According to an example, the voltage EPR_ON is generated and/or delivered by a processor internal or external to the circuitry comprising the voltage matching circuit 400.

Voltage matching circuit 400 comprises a circuit 401 (COMP) for comparing two voltages. Circuit 401 receives, as an input, the voltage VBUS and the threshold voltage Vth, and delivers, as an output, a voltage VComp, or a signal VComp, indicating the result of the comparison of the voltage VBUS with the threshold voltage Vth.

Circuit 400 further comprises a circuit 402 (/n) for dividing a voltage. Circuit 402 receives, as an input, the voltage VBUS, and delivers, as an output, a voltage VBUSn equal to the voltage VBUS divided by a factor n. The factor n is sized so that the voltage VBUSn is less than a maximum voltage Vmax that can receive a monitoring circuit with which the circuit 400 is associated, that is a circuit of the type of the circuit 302 described in relation with FIG. 3. According to an example, if the monitoring circuit is only adapted to monitor VBUS when a supply pattern of the standard range is used, the voltage Vmax is comprised between 20 and 30 V, for example in the order of 28 V. According to an example, the factor n is between 2 and 5, for example in the order of 3. According to an example, circuit 400 comprises a voltage divider bridge. In some embodiments, the factor n is an integer value; however, embodiments are not limited thereto.

Circuit 400 further and lastly comprises a circuit 403 (SEL) for selecting. Circuit 403 delivers, as an output, the voltage VBUSMON, and receives, as an input, voltages VBUS and VBUSn. Circuit 403 is further controlled by the voltage VComp and the voltage EPR_ON.

The operation of the circuit 400 is as follows. When the USB PD protocol is implemented, and the voltage VBUS is present, the comparison circuit 401 compares the voltages VBUS and Vth with each other. If the voltage VBUS is less than the voltage Vth, the implemented supply pattern is a part of the standard range SPR. If the voltage VBUS is higher than the voltage Vth, it is possible that the implemented supply pattern is a part of the extended region EPR. The voltage VComp indicates the result of the comparison, for example by a high level when the voltage VBUS is higher than the threshold voltage Vth, and by a low level when the voltage VBUS is less than the threshold voltage Vth, or vice-versa. Concurrently, the voltage VBUSn corresponding to the voltage VBUS divided by the factor n, is generated by circuit 402. Alternatively, circuit 402 may also be activated by the comparison voltage VComp, and deliver the voltage VBUSn only where needed.

The selection circuit 403 is adapted to deliver the voltage VBUSMON as an output, and this voltage VBUSMON is equal to: the voltage VBUS, when the result of the comparison indicates that the voltage VBUS is less than the voltage Vth; or the voltage VBUSn, when the result of the comparison indicates that the voltage VBUS is higher than the voltage Vth and the voltage EPR_ON indicates that the implemented supply pattern is a part of the extended range EPR.

An advantage of circuit 40o is it allows the level of the voltage VBUS to be matched so that a supply pattern of the extended range EPR is monitored using a monitoring circuit adapted only to the monitoring of the supply pattern of the standard range. Thus, it is possible to add a circuit of the type of the circuit 40o to modules or portions of circuitry adapted only to the standard range.

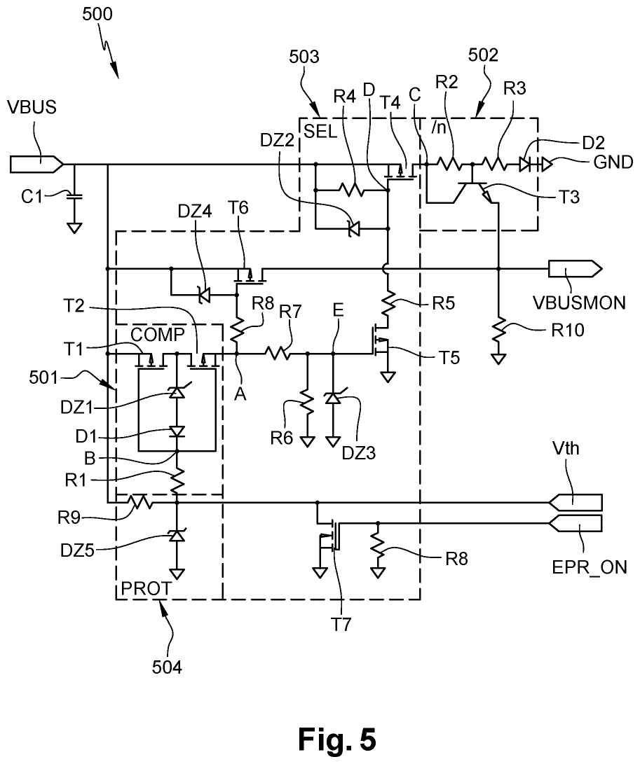

FIG. 5 illustrates a more detailed embodiment of a voltage matching circuit 500 of the type of the circuit 400 described in relation with FIG. 4. In other words, circuit 500 is a detailed example embodiment of the circuit 400 of FIG. 4.

Like the circuit 40o described in relation with FIG. 4, circuit 500 comprises: a comparison circuit 501 (COMP) of the type of the circuit 401 described in relation with FIG. 4; a voltage dividing circuit 502 (/n) of the type of the circuit 402 described in relation with FIG. 4; and a selection circuit 503 (SEL) of the type of the circuit 403 described in relation with FIG. 4.

The comparison circuit 501 comprises two transistors T1 and T2, two diodes DZ1 and D2, and a resistor R1.

The transistors T1 and T2 are insulated-gate field-effect transistors, or field-effect transistors with metal-oxide-semiconductor structure, hereafter called MOSFET (Metal Oxide Semiconductor Field Effect Transistor) or MOS transistors. In addition, the transistors T1 and T2 are P-channel MOS transistors, or P-type MOS transistors or PMOS transistors. Furthermore, the N-channel MOS transistors are hereafter called N-type MOS transistors, or NMOS transistors. The drain of transistor T1 is coupled, preferably connected, with a node receiving the voltage VBUS, and the source of transistor T1 is coupled, preferably connected, with the source of transistor T2. The drain of transistor T2 is coupled, preferably connected, with a node A. The gates of the transistors T1 and T2 are coupled with each other and with a node B.

Diodes DZ1 and D1 are serially coupled head to tail between the drain of transistor T1, or the drain of transistor T2, and node B. More particularly, the cathode of diode DZ1 is coupled, preferably connected, with the drain of transistor T1, and the anode of diode DZ1 is coupled, preferably connected, with the anode of diode D2. The cathode of diode D2 is coupled, preferably connected, with node B. In addition, the diode DZ1 is a Zener diode.

Resistor R1 couples the node B with a node receiving the threshold voltage Vth. According to an example, the resistor R1 has a resistance of 100 kOhm.

The voltage dividing circuit 502 comprises two resistors R2 and R3, a transistor T3, and a diode D2.

The resistors R2 and R3 are serially coupled with a node C and the anode of diode D2. According to an example, the resistor R2 has a resistance of 20 kOhm, and the resistor R11 has a resistance of 10 kOhm.

The diode D2 has its cathode coupled, preferably connected, with a node GND, represented by a triangle in FIG. 5 and receiving a reference voltage, for example ground.

The transistor T3 is a NPN-type bipolar transistor. The gate of transistor T3 is coupled, preferably connected, with the medium node between the resistors R2 and R3. The emitter of transistor T3 is coupled, preferably connected, with the node delivering the voltage VBUSMON, and the collector of transistor T3 is coupled, preferably connected, with node C. The transistor T3 is optional, and has a function of buffer of current source.

The factor n of the circuit 502 is set by the ratio of the sum of the resistances of the resistors R2 and R3, to the resistance of the resistor R3. According to an example, the factor n is equal to 3.

The selection circuit 503 comprises four transistors T4, T5, T6, and T7, seven resistors R4, R5, R6, R7, R8, R9, and R10, and three Zener diodes DZ2, DZ3, DZ4.

The transistor T4 is a P-type MOS transistor. The drain of transistor T4 is coupled, preferably connected, with node C, and the source of transistor T4 is coupled, preferably connected, with the node receiving the voltage VBUS. The gate of the transistor T4 is coupled, preferably connected, with a node D.

The resistor R4 and the diode DZ2 are coupled in parallel between node D and the node receiving the voltage VBUS. More particularly, the anode of diode DZ2 is coupled, preferably connected, with node D, and the cathode of diode DZ2 is coupled, preferably connected, with the node receiving the voltage VBUS. According to an example, resistor R5 has a resistance in the order of boo kOhm.

The resistance R5 and the transistor T5 are series coupled between the node D and the node GND. The transistor T5 is a N-type MOS transistor. More particularly, a first terminal of resistor R5 is coupled, preferably connected, with node D, and a second terminal of resistor R5 is coupled, preferably connected, with the drain of transistor T5. The source of transistor T5 is coupled, preferably connected, with node GND. The gate of transistor T5 is coupled, preferably connected, with a node E. According to an example, resistor R5 has a resistance in the order of 10 kOhm.

The resistor R6 and the diode DZ3 are coupled in parallel between node E and node GND. More particularly, the anode of diode DZ3 is coupled, preferably connected, with the node GND, and the cathode of diode DZ3 is coupled, preferably connected, with the node E. According to an example, resistor R6 has a resistance in the order of 100 kOhm.

The resistor R7 couples the nodes E and A. According to an example, resistor R7 has a resistance in the order of 10 kOhm.

The transistor T6 is a P-type MOS transistor, and couples the node receiving the voltage VBUS with the node delivering the voltage VBUSMON. More particularly, the drain of transistor T6 is coupled, preferably connected, with the node delivering the voltage VBUSMON. The source of transistor T6 is coupled, preferably connected, with the node receiving the voltage VBUS. The resistor R8 couples the gate of transistor T6 with node A. According to an example, resistor R8 has a resistance in the order of 10 kOhm. The diode DZ4 couples the gate of transistor T6 with its source. More particularly, the anode of diode DZ4 is coupled, preferably connected, with the gate of transistor T6, and the cathode of diode DZ4 is coupled, preferably connected, with the source of transistor T6.

The transistor T7 is a N-type MOS transistor. The drain of transistor T7 is coupled, preferably connected, with the node receiving the threshold voltage, and the source of transistor T7 is coupled, preferably connected, with node GND. The gate of transistor T7 is coupled, preferably connected, with the node receiving the voltage EPR_ON. The resistor R8 couples the gate of transistor T7 with node GND. According to an example, resistor R8 has a resistance in the order of 100 kOhm.

Circuit 500 further and optionally comprises a protection circuit 504, comprising a diode DZ5 and a resistor R9. Diode Z5 is a Zener diode coupling the node receiving the threshold voltage Vth with node GND. More particularly, the cathode of diode DZ5 is coupled, preferably connected, with the node receiving the threshold voltage Vth, and the anode of diode DZ5 is coupled, preferably connected, with node GND. Resistor R9 couples the node receiving the voltage Vth with the node receiving the voltage VBUS.

Circuit 500 has the function to control the selection circuit in the case the voltage VBUS is higher than the threshold voltage Vth, and the voltage EPR_ON indicates that a supply pattern of the standard range is used. Circuit 500 thus allows the monitoring circuit of the type of the circuit 302 described in relation with FIG. 3 to be protected against an abnormal increase of the voltage VBUS.

Circuit 500 further comprises a filter capacitor Ci coupling the node receiving the voltage VBUS with node GND. According to an example, capacitor Ci has a capacitance in the order of 10 μF.

Circuit 500 further and lastly comprises a resistor R10 coupling the node receiving the voltage VBUSMON with node GND. According to an example, resistor R10 has a resistance in the order of 40 kOhm.

Diodes D1, DZ1, DZ2, and DZ3 are protective diodes.

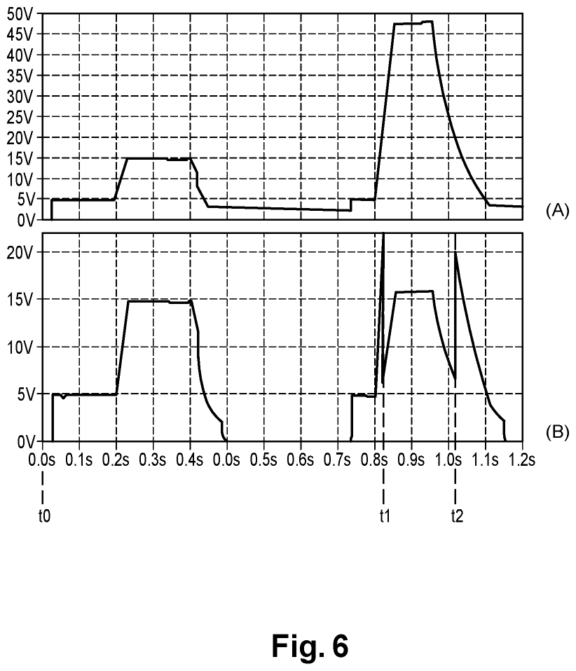

The operation of the circuit 500 is described in relation with FIG. 6.

FIG. 6 comprises two graphs (A) and (B) representing the evolution over the time of the voltage VBUS and of the voltage VBUSMON, respectively. In this example, the threshold voltage Vth is in the order of 20 V.

Between a first time to and a time t1, the voltage VBUS varies between 0 and Vth, that is 20 V in the example represented in FIG. 6. The voltage VBUSMON follows the evolution of the voltage VBUS, and is equal to the voltage VBUS.

From time t1, until a time t2, the voltage VBUS exceeds the threshold voltage Vth, and the voltage VBUSMON decreases to reach the level of the voltage VBUSn. In the case herein represented, the factor n is in the order of 3.

After time t2, the voltage VBUS is less than the threshold voltage Vth, and the voltage VBUSMON increases to go back to the level of voltage VBUS.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

What is claimed is:

1. A voltage matching circuit configured to receive a first voltage received by a connector, and output a second voltage equal to:
the first voltage, in response to the first voltage being less than a threshold voltage; or
the first voltage divided by a first factor, in response to the first voltage being greater than or equal to the threshold voltage.

2. The voltage matching circuit according to claim 1, comprising a comparator circuit configured to compare the first voltage with the threshold voltage.

3. The voltage matching circuit according to claim 1, comprising a division circuit configured to divide the first voltage by the first factor.

4. The voltage matching circuit according to claim 3, wherein the division circuit comprises a voltage divider bridge.

5. The voltage matching circuit according to claim 3, wherein the first factor is in the order of 3.

6. The voltage matching circuit according to claim 1, comprising a selection circuit configured to output the second voltage by selectively coupling an output node with either with a first node at the first voltage, or with a second node at a voltage equal to the first voltage divided by the first factor.

7. The voltage matching circuit according to claim 6, wherein the selection circuit is configured to be controlled by an output voltage of a comparator circuit.

8. The voltage matching circuit according to claim 6, wherein the selection circuit is configured to be controlled by a control voltage.

9. The voltage matching circuit according to claim 8, wherein the control voltage is a voltage indicating if the connector is supposed to receive the first voltage at a voltage that is greater than the threshold voltage or not.

10. The voltage matching circuit according to claim 1, wherein the connector is a USB Type-C connector configured to implement USB PD protocol.

11. An electronic device, comprising:
a connector; and
a voltage matching circuit coupled to the connector to receive a first voltage and to output a second voltage equal to:
the first voltage, in response to the first voltage being less than a threshold voltage; or
the first voltage divided by a first factor, in response to the first voltage being greater than or equal to the threshold voltage.

12. The electronic device according to claim 11, further comprising a monitoring circuit configured to receive the second voltage output by the voltage matching circuit.

13. The electronic device according to claim 12, wherein the monitoring circuit is configured to monitor a voltage less than 20 V.

14. The electronic device according to claim 11, wherein the connector is a USB Type-C connector configured to implement USB PD protocol.

15. A method, comprising:
receiving a first voltage by a connector; and
outputting a second voltage, the second voltage being equal to:
the first voltage, in response to the first voltage being less than a threshold voltage; or
the first voltage divided by a first factor, in response to the first voltage being greater than or equal to the threshold voltage.

16. The method according to claim 15, further comprising:
comparing, by a comparator circuit, the first voltage with the threshold voltage.

17. The method according to claim 15, further comprising:
dividing, by a division circuit, the first voltage by the first factor.

18. The method according to claim 15, further comprising:
outputting, by a selection circuit, the second voltage by selectively coupling an output node with either with a first node at the first voltage, or with a second node at a voltage equal to the first voltage divided by the first factor.

19. The method according to claim 18, further comprising:
controlling the selection circuit by an output voltage of a comparator circuit.

20. The method according to claim 18, further comprising:
controlling the selection circuit by a control voltage, the control voltage indicating whether the connector is supposed to receive the first voltage at a voltage that is greater than or less than the threshold voltage.
